(19) United States
(12) Patent Application Publication
(10) Pub. No.: US 2025/0308939 A1
(43) Pub. Date: Oct. 2, 2025

(54) LEADFRAME AND ELECTRONIC DEVICE SINGULATION PROCESS

(71) Applicants: Anis Fauzi BIN ABDUL AZIZ, BATU BERENDAM (ML); Wei Fen Sueann LIM, MELAKA (ML); Mahendra LETCHMANAN, PETALING JAYA (ML); Han Meng LEE, CHERAS (ML)

(72) Inventors: Anis Fauzi BIN ABDUL AZIZ, BATU BERENDAM (ML); Wei Fen Sueann LIM, MELAKA (ML); Mahendra LETCHMANAN, PETALING JAYA (ML); Han Meng LEE, CHERAS (ML)

(21) Appl. No.: 18/622,851

(22) Filed: Mar. 29, 2024

(51) Int. Cl. H01L 21/56; H01L 21/48; H01L 23/00; H01L 23/495; H01L 25/065

(52) U.S. Cl. CPC H01L 21/561; H01L 21/4821; H01L 23/49575; H01L 24/37; H01L 24/45; H01L 24/97; H01L 25/0652; H01L 2224/37005; H01L 2224/3702; H01L 2224/45005; H01L 2224/4502; H01L 2224/97; H01L 2924/182

(57) ABSTRACT

An electronic device and method are provided. The method includes providing an array of electronic devices having leadframes where the leadframes include at least one depopulated lead and external leads interconnected by a first dambar, a second dambar, and a connection assembly. The connection assembly connects the first dambar to a first external lead of a first leadframe and to a second external lead of a second adjacent leadframe. A first punch process is performed to remove the first dambar and the second dambar from the leadframes. A second punch process is performed to create a cut in the connection assembly proximate the first external lead adjacent to the at least one depopulated lead to disconnect the connection assembly from the first external lead. A trimming process is performed to trim external leads of the leadframes to their required length while simultaneously removing the connection assembly.

### TECHNICAL FIELD

The present disclosure relates to a leadframe for an electronic device and more specifically, to a leadframe and a leadframe singulation process for integrated circuit packages.

### BACKGROUND

During fabrication of an array of integrated circuit (IC) packages with external leads (e.g., DIP, SOP, etc.), the IC packages undergo a singulation process to separate the IC packages from the array. Specifically, during singulation, one or more punching processes may be performed to remove dambars between adjacent leadframes to thereby separate the IC packages from the array. In addition, one or more trimming processes may be performed to trim the external leads to its required length.

### SUMMARY

In a described example, a method includes providing an array of electronic devices having leadframes where the leadframes include at least one depopulated lead and external leads interconnected by a first dambar, a second dambar, and a connection assembly. The connection assembly connects the first dambar to a first external lead of a first leadframe and to a second external lead of a second leadframe, the second leadframe being adjacent to the first leadframe A first punch process is performed to remove the first dambar and the second dambar from the leadframes. A second punch process is performed to create a cut in the connection assembly proximate the first external lead adjacent to the at least one depopulated lead to disconnect the connection assembly from the first external lead. A trimming process is performed to trim external leads of the leadframes to their required length while simultaneously removing the connection assembly.

In another described example, an array of electronic devices includes an array of interconnected leadframes. The leadframes includes at least one depopulated lead, a first dambar interconnecting external leads on a leadframe and external leads on an adjacent leadframe. A second dambar interconnects the external leads on the adjacent leadframe and the external leads on the leadframe. A connection assembly connects the first dambar to both a first external lead on the leadframe and to a second external lead on the adjacent leadframe. A die is attached to each of the array of leadframes.

In still another described example, an electronic device includes a leadframe having a die pad and leads comprised of at least one depopulated lead, inner leads, and external leads. The external leads include a first protrusion on either side of each of the external leads. At least one external lead includes a second protrusion on each side of the at the least one external lead. A die is disposed on the die pad via a die attach material and wire bonds are attached to an active side of the die and to a surface of the inner leads. A mold compound encapsulates the die, the die pad, the wire bonds, and the inner leads.

### BRIEF DESCRIPTION OF THE DRAWINGS

FIGS. 1A and 1B are side and top views respectively an example electronic device.

FIG. 2 is a block diagram flow chart illustrating a fabrication process for the electronic device of FIGS. 1A and 1B.

FIG. 3A is a top view of a wafer that includes dies.

FIG. 3B illustrates a cross-sectional view of a singulated die from the wafer in FIG. 3A in the early stages of fabrication of the electronic device.

FIG. 3C illustrates a cross-sectional of the die in FIG. 3B after forming a die attach material on a non-active surface of the die.

FIG. 3D illustrates a cross-sectional view of a leadframe in the early stages of assembly of the electronic device.

FIG. 3E illustrates a cross-sectional view of the electronic device of FIG. 3D with the die attached to the leadframe.

FIG. 3F illustrates a cross-sectional view of the electronic device of FIG. 3E after undergoing a wire bonding process.

FIG. 3G illustrates a cross-sectional view of the electronic device of FIG. 3F after undergoing formation of a mold compound.

FIG. 3H illustrates a top view of a partial array of the electronic device of FIG. 3G.

FIG. 3I illustrates a top view of the partial array of FIG. 3H undergoing a first punch (cutting) process.

FIG. 3J illustrates a top view of the partial array of FIG. 3I after undergoing the first punch process to remove dambars.

FIG. 3K illustrates a top view of the partial array of FIG. 3J undergoing a second punch (cutting) process.

FIG. 3L illustrates a top view of the partial array of FIG. 3K after undergoing the second punch process to create a cut in a connection assembly of the leadframe.

FIG. 3M illustrates a top view of the partial array of FIG. 3L undergoing a trimming process to trim external leads of the leadframe to a required length.

FIG. 3N illustrates a top view of the partial array of FIG. 3M after undergoing the trimming process.

### DETAILED DESCRIPTION

During fabrication of an array of integrated circuit (IC) packages with external leads (e.g., DIP, SOP, etc.), the IC packages undergo a singulation process to separate the IC packages from the array. Specifically, during singulation, one or more punching processes may be performed to remove dambars between adjacent leadframes to thereby separate the IC packages from the array. IC packages, however, have different configurations based on the application of the IC package. More specifically, some IC packages may require more or less external leads than other IC packages. For example, one IC package may have four external leads on each side of the package for a specific application, and another IC package may have at least one depopulated lead. A depopulated lead is defined as a leadframe having at least one lead omitted from the leadframe during fabrication of the leadframe. For example, the IC package may have four external leads on one side of the package and only three external leads on an opposite side of the package. As a result, one punch tool is required for the first example with four external leads on each side of the package, and another different punch tool is required for the second example with four external leads on one side of the package and only three external leads the opposite side of the package. Thus, it becomes rather costly to invest in multiple tooling to fabricate different IC packages having a slightly different lead configurations.

Disclosed herein is a leadframe and an electronic device singulation process to overcome the aforementioned disadvantages. The leadframe is a specially designed leadframe for applications where less than the normal amount of leads are required for the give application. For example, some IC packages may have four external leads on opposite sides of the package. In an application where only three external leads are required on one side of the package, the leadframe is designed to exclude the unrequired lead. In addition, a connection is provided from the dambar where the depopulated lead would normally reside to an adjacent lead.

The singulation process includes a first punching (cutting) process to remove the dambars. The singulation process further include a second punching (cutting) process to remove the connection from the dambar to the adjacent lead. Finally, the external leads are trimmed to their required length. During the final trimming process, the extra connection for the depopulated lead is also removed. The punch (cutting) tool and the trimming tool required for removal of the dambars and the trimming of the external leads respectively are the same tools regardless if there are no depopulated leads or any number (e.g., 1, 2, 3, etc.) of depopulated leads. Thus, the same tools can be used for any leadframe configuration and IC package application thereby reducing fabrication costs.

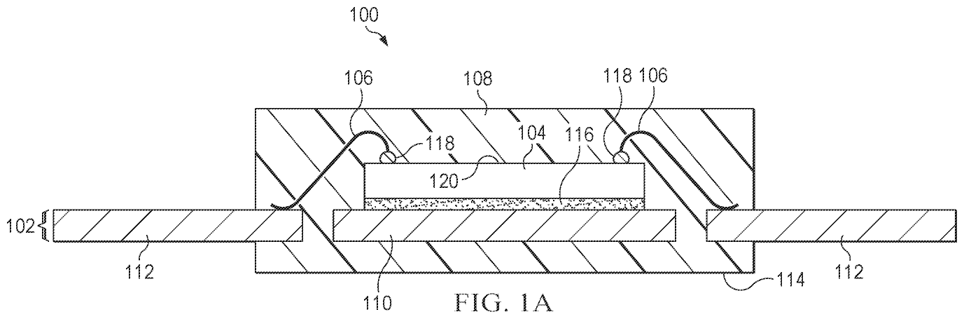

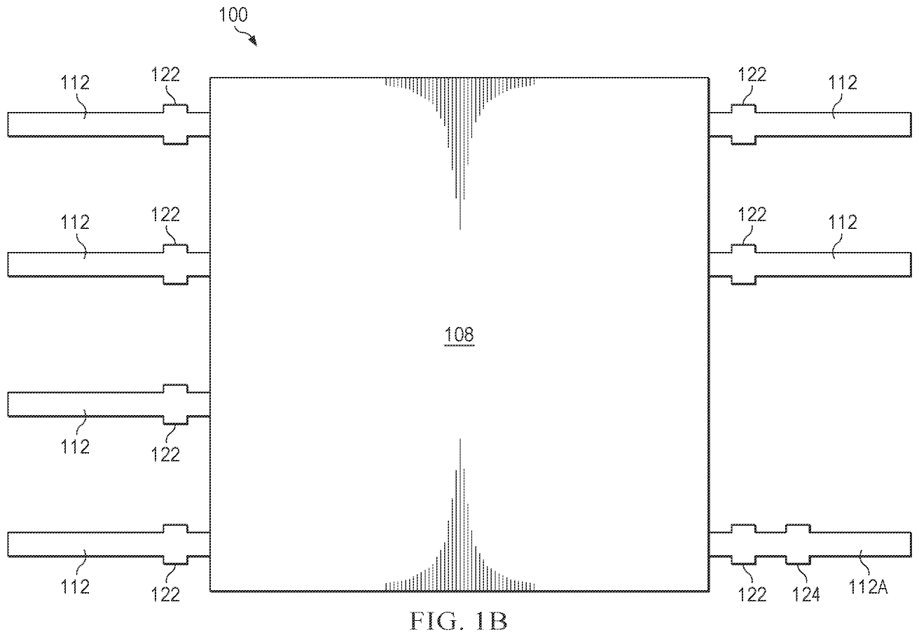

FIGS. 1A and 1B are cross sectional and top views respectively of an example electronic device (e.g., integrated circuit (IC)) 100. The electronic device 100 includes a substrate 102, a die 104 disposed on the substrate 102, wire bonds 106, and a mold compound 108. The electronic device 100 can be comprised of a leaded integrated circuit (IC) including, but not limited to a Quad-Flat Package (QFP), a Dual In-Line Package (DIP), a Single In-Line Package (SIP), Small Outline Package (SOP), etc. In addition, the electronic device 100 can be a through-hole mount or a surface mount package. Thus the example electronic device 100 in FIGS. 1A and 1B is illustrated before the external leads are shaped or formed to accommodate a through-hole or surface mount application. Therefore, the electronic device 100 illustrated in FIGS. 1A and 1B is for illustrative purposes only and is not intended to limit the scope of the invention.

The substrate 102 is comprised of a leadframe that includes a die pad 110 and external leads 112. In some examples, the die pad 110 may be comprised of a thermal pad that is exposed (no shown) on an attachment side 114 of the electronic device 100. The thermal pad creates an efficient heat path away from the electronic device 100 to a board (e.g., printed circuit board). In addition, the exposed thermal pad or die pad 110 also enables a ground connection to the board. The die 104 attaches to the die pad 110 via a die attach material 116.

The wire bonds 106 are connected to the ball bonds 118 and provide a connection between an active surface 120 of the die 104 and the external leads 112. The mold compound 108 encapsulates the die 104, the wire bonds 106, and the ball bonds 118. In some examples, the mold compound 108 covers all but one surface of the substrate 102, where the one surface not covered faces away from the die 104 and the electronic device 100.

After the singulation process, explained further below, protrusions 122 are formed on the external leads 112 due to the removal of dambars. In addition, due to the design of the substrate (leadframe) 102, an extra (second) protrusion 124 is formed on an external lead 112A that is adjacent to the depopulated lead. The extra protrusion 124 is the result of a connection from the dambar to the adjacent external lead 112A.

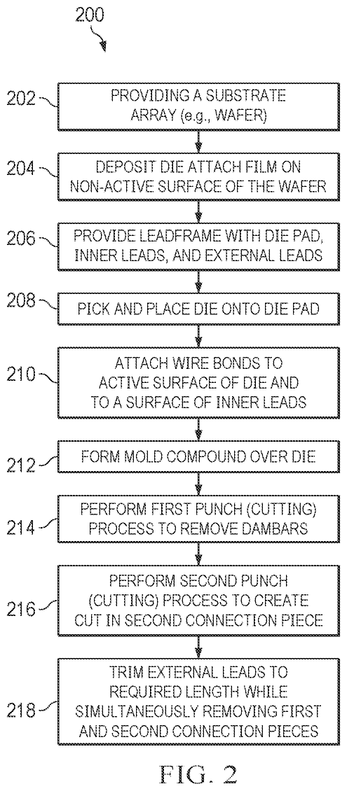

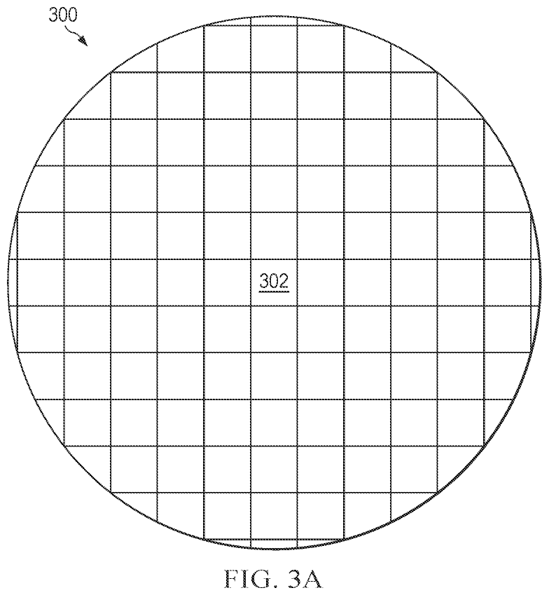

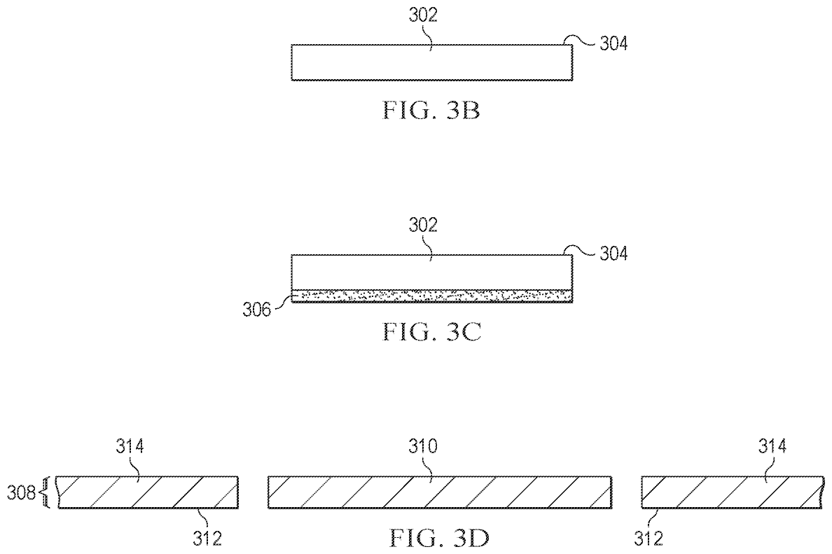

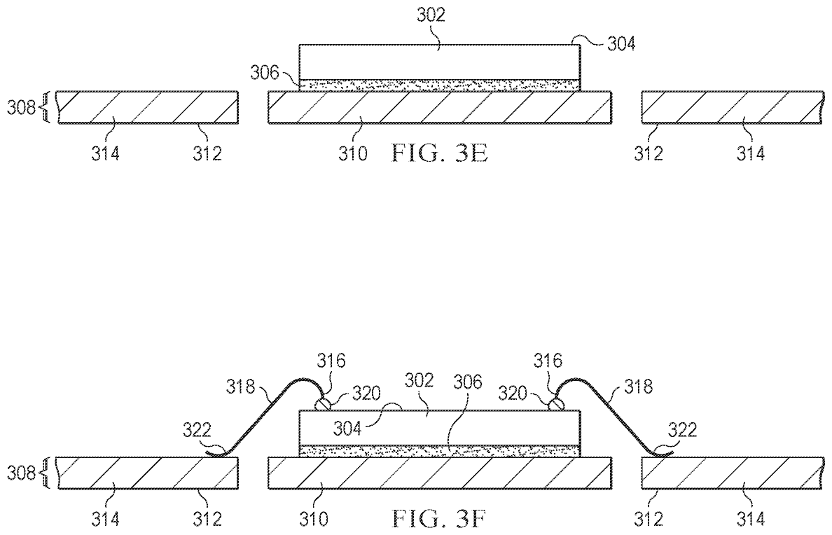

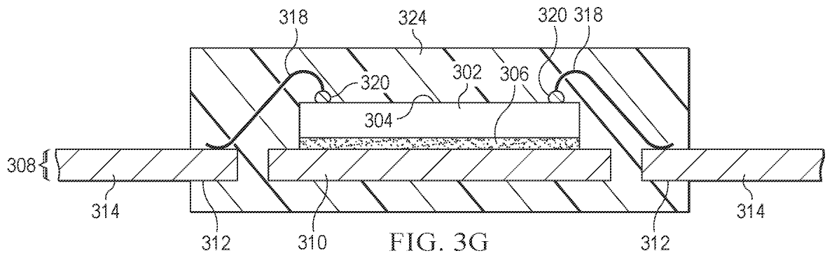

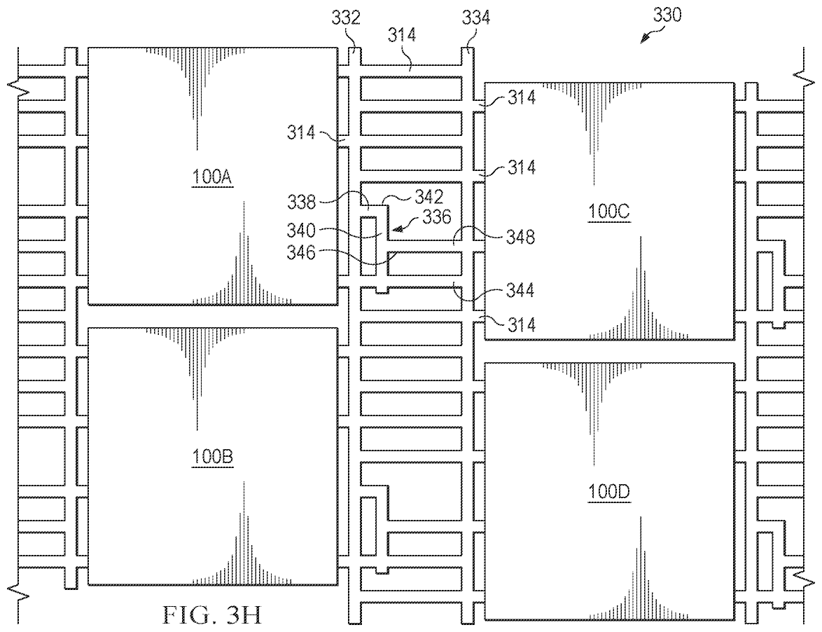

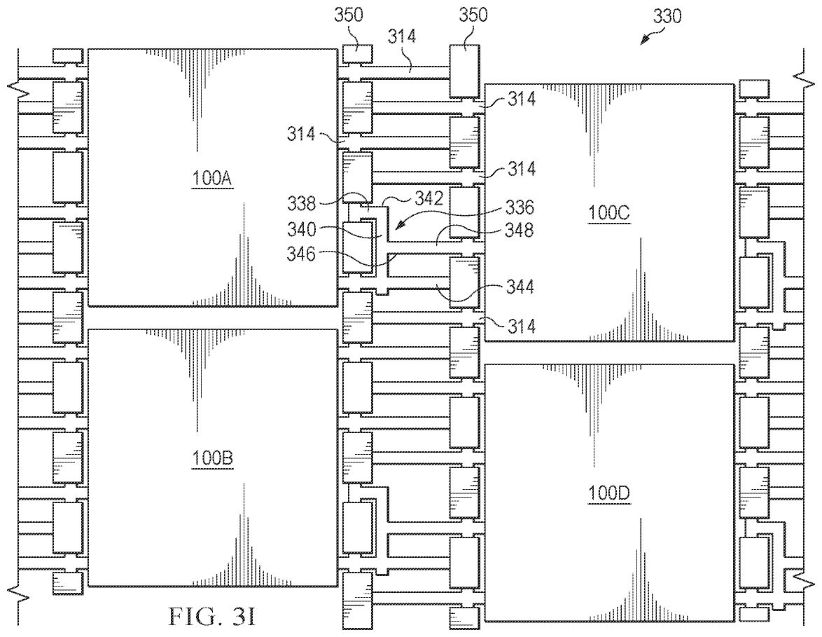

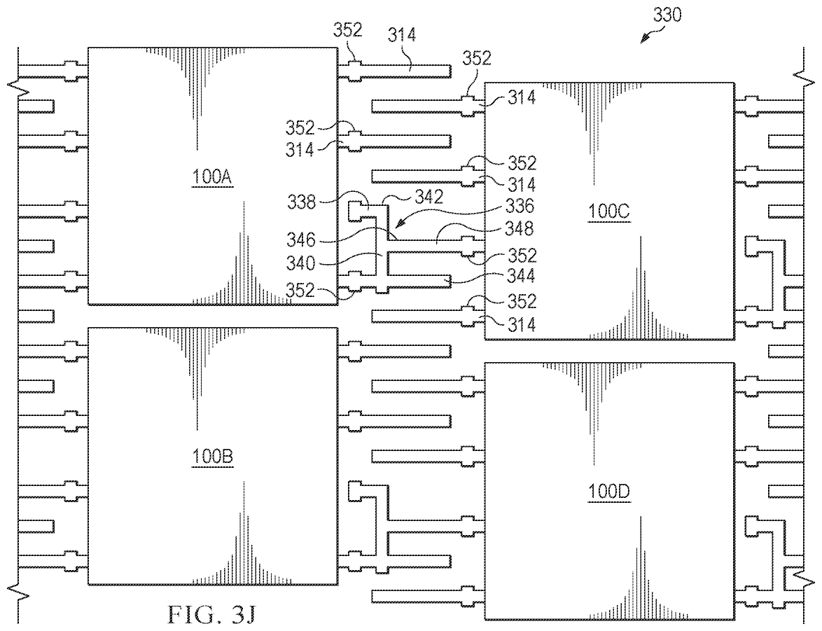

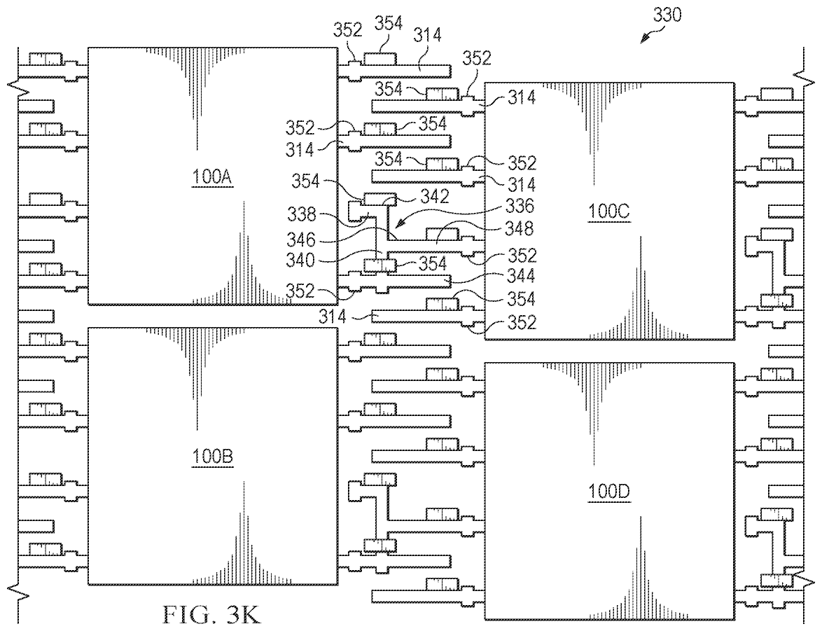

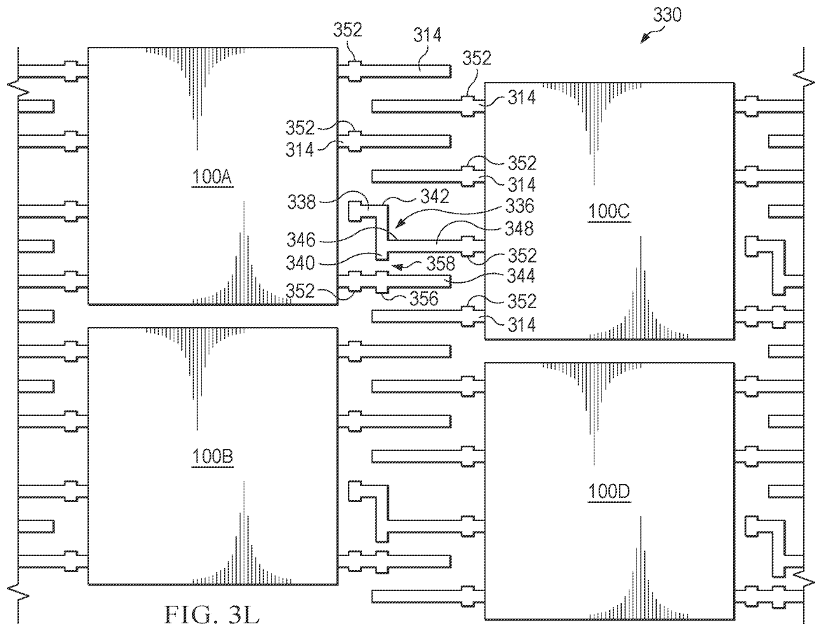

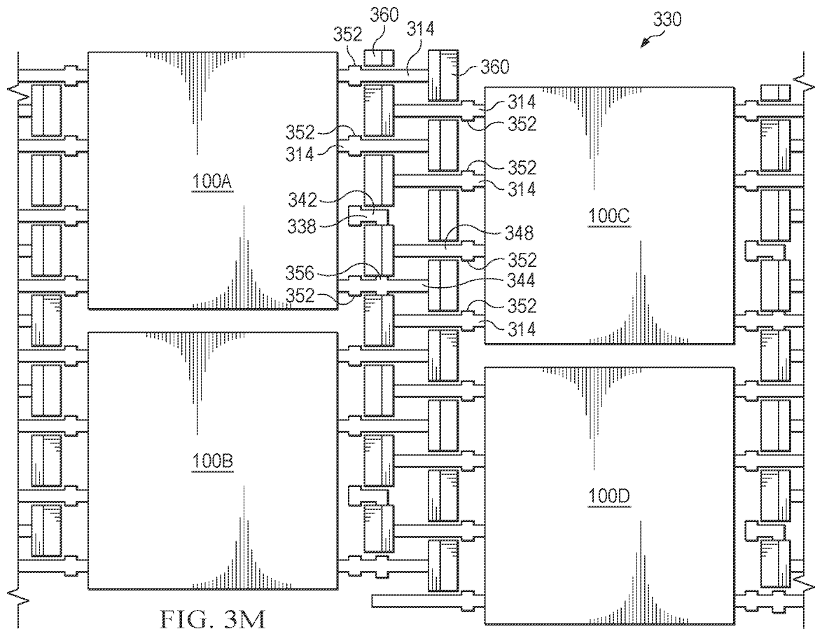

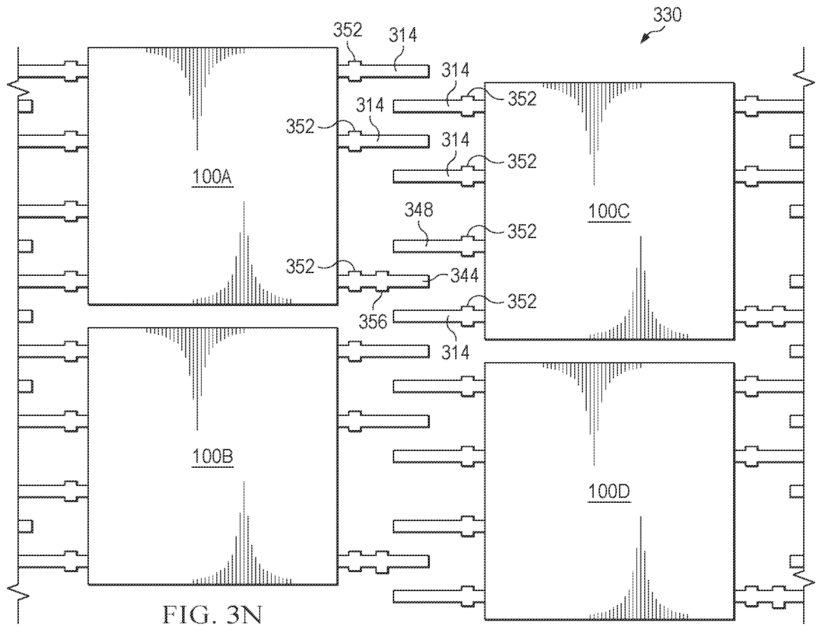

FIG. 2 is a block diagram flow chart explaining a fabrication process 200 and FIGS. 3A-3N illustrate a fabrication process associated with the formation of the electronic device 100 illustrated in FIGS. 1A and 1B. Though depicted sequentially as a matter of convenience, at least some of the actions shown can be performed in a different order and/or performed in parallel. Alternatively, some implementations may perform only some of the actions shown. Still further, although the example illustrated in FIGS. 2 and 3A-3N is an example method illustrating the example configuration of FIGS. 1A and 1B, other methods and configurations are possible. It is understood that although the method illustrated in FIGS. 2 and 3A-3N depicts the fabrication process of a single electronic device, the process applies to an array electronic devices. Thus, after fabrication of the array of electronic devices the array is singulated to separate each electronic device 100 from the array.

Referring to FIG. 2 and to FIGS. 3A-3N, the fabrication process of the electronic device 100 illustrated in FIGS. 1A and 1B begins at 202 with a wafer 300, as illustrated in FIG. 3A. Specifically, FIG. 3A is a schematic diagram of a wafer 300, in accordance with various examples. For example, the wafer 300 may be a silicon wafer. The wafer 300 comprises multiple dies 302. The manufacturing techniques described below may be performed on individual dies 302 (post-singulation), or the techniques may be more efficiently performed on a mass scale, e.g., simultaneously on multiple dies 302 of the wafer 300 (pre-singulation). For convenience and clarity, the remaining drawings show one die 302, with the understanding that the processes described herein as being performed on the die 302 may also be performed (e.g., sequentially performed, simultaneously performed) on the remaining dies 302 of the wafer 300.

FIG. 3B illustrates a cross sectional view of a single die 302 of the wafer 300 where the die 302 includes an active side 304. At 204, a die attach film 306 is applied to a side of the die 302 opposite that of the active side 304 resulting in the configuration of FIG. 3C. In an alternative example, a die attach material may be deposited on a die pad of a leadframe prior to attaching the die 302 to the die pad.

Referring to FIG. 3D, at 206, a leadframe 308 is provided where the leadframe 308 includes a die pad 310, inner leads 312, and external leads or conductive terminals 314. At 208, the die 302 is picked and placed on the die pad 310 via the die attach film 306 resulting in the configuration of FIG. 3E. At 210, a first end 316 of wire bonds 318 is attached via a ball bond (e.g., solder ball) 320 to the active side 304 of the die 302 and a second end 322 of the wire bonds 318 is attached to a surface of each of the inner leads 312 resulting in the configuration in FIG. 3F. At 212, a mold compound 324 is formed over the die 302. Specifically, the mold compound 324 encapsulates the die 302, the wire bonds 318, and the ball bonds 320 resulting in the configuration of FIG. 3G. In some examples (not shown), the mold compound 324 may cover all but one surface of the die pad 310, where the one surface not covered faces away from the die 302.

After assembly of the electronic devices 100, the array of electronic devices 100 undergo a singulation process to separate the electronic devices 100 from one another. The illustrations in FIGS. 3H-3N represent a top view of a partial array 330 of four electronic devices 100A-100D undergoing the singulation process. For simplicity, the external leads on the opposite side of the four electronic devices 100A-100D are omitted. For illustration purposes, it is assumed that the number of external leads on the opposite side of electronic devices 100A and 100B is four and number of external leads on the opposite side of electronic devices 100C and 100D is three, as illustrated in FIG. 3N.

FIG. 3H is an illustration of the partial array 330 of the electronic devices 100A-100D having re-configured leadframes 308 that have at least one depopulated lead. The leadframes 308 of the electronic devices 100A-100D are interconnected via a first dambar 332 and a second dambar 334. Specifically, the first and second dambars 332, 334 connect the external leads 314 of adjacent electronic devices 100A-100D, and more specifically of adjacent leadframes 308. In addition, the first and second dambars 332, 334 are connected to a proximate end (the end closest to the die 302 and mold compound 324) of the external leads of respective packages. As previously mentioned, the leadframes 308 of electronic devices 100A and 100B have at least one depopulated lead. Thus, the number of external leads 314 extending out one side of electronic devices 100A and 100B is three. Although, not illustrated in FIGS. 3H-3M, it is to be understood that the number of external leads 314 extending from the same side of electronic devices 100C and 100D is also three (see FIG. 3N).

For ease of description, reference will be made only to the leadframe 308 of electronic device 100A. The re-configured leadframe 308 includes a connection assembly 336 comprised of a first connection piece 338 and a second connection piece 340. The connection assembly 336 compensates for the absence of one or more depopulated leads to assist in providing a connection between adjacent leadframes 308. The first connection piece 338 extends substantially from the first dambar 332 toward the second dambar 334 in a location where the depopulated lead would normally reside. The second connection piece 340 extends from a distal end 342 of the first connection piece 338 substantially perpendicular to the first connection piece 338 and substantially parallel to the first and second dambars 332, 334. The second connection piece 340 connects to an (a first) external lead 344 adjacent to the depopulated lead of the electronic device 100A proximate the first dambar 332. In addition, a distal end 346 of an (a second) external lead 348 of the adjacent electronic device 100C is connected to the second connection piece 340 between the first connection piece 338 and the external lead 344. Thus, the second connection piece 340 serves as a dambar to stabilize the external lead 348 of the adjacent electronic device 100C during the electronic device assembly process.

As illustrated in FIG. 3I, at 214, the configuration of FIG. 3H undergoes a first punch (cutting) process via a first punch or cutting tool 350 to remove the first and second dambars 332, 334 resulting in the configuration of FIG. 3J. Since the first punch tool 350 does not cut flush along the external leads, 314, 344, 348, first protrusions 352 remain from the first and second dambars 332, 334 on either side of the external leads 314, 344, 348. As illustrated in FIG. 3K, at 216, the configuration of FIG. 3J undergoes a second punch (cutting) process via a second punch or cutting tool 354. The second punch process creates a cut 358 in the second connection piece 340 proximate to the external lead 344 to disconnect the second connection piece 340 from the external lead 344 adjacent to the depopulated lead in the electronic device 100A resulting in the configuration of FIG. 3L. During the second punching process, the second punch tool 354 does not interfere with any portion of the leadframe 308 or external leads 314 where there is no connection assembly 336 present. Thus, the second punching tool 354 can be used for other leadframe configurations where there may be no depopulated leads, more than one depopulated leads on one side of the leadframe, or one or more than one depopulated leads on both sides of the leadframe.

Second protrusions 356 are formed on both sides of the external lead 344 adjacent to the depopulated lead. Specifically, during configuration of the leadframe 308, the second connection piece 340 is connected such that it extends past the external lead 344 thereby forming a protrusion 356 on one side of the external lead 344. In addition, since the second punch tool 354 does not cut flush along the external lead 344, a protrusion 356 is formed on the opposite side of the external lead 344. Thus, second protrusions 356 are formed on both sides of the external lead 344 as a result of the second connection piece 340.

As illustrated in FIG. 3M, at 218, the configuration in FIG. 3L undergoes a trimming process via a trimming tool 360 to cut the external leads, 314, 344, 348 to their required length. During the trimming process, since the second connection piece 340 is already disconnected from the external lead 344, the connection assembly 336 is connected only to the external lead 348 on the adjacent electronic device 100C. Thus, when the external leads 314, 344, 348 are trimmed, the entire connection assembly 336 is simultaneously removed resulting in the configuration of FIG. 3N.

The connection assembly in the reconfigured leadframes serves as a stabilizer in the absence of one or more depopulated leads to provide stability to the leadframes during the assembly and singulation processes of the electronic devices. In addition, the reconfigured leadframes that include the connection assembly allow the usage of the same singulation tools to be used for any leadframe configuration. For example, the same singulation tools can be used for configurations having no depopulated leads or one or more depopulated leads thereby reducing manufacturing material and production costs.

Described above are examples of the subject disclosure. It is, of course, not possible to describe every conceivable combination of components or methodologies for purposes of describing the subject disclosure, but one of ordinary skill in the art may recognize that many further combinations and permutations of the subject disclosure are possible. Accordingly, the subject disclosure is intended to embrace all such alterations, modifications and variations that fall within the spirit and scope of the appended claims. In addition, where the disclosure or claims recite “a,” “an,” “a first,” or “another” element, or the equivalent thereof, it should be interpreted to include one or more than one such element, neither requiring nor excluding two or more such elements. Furthermore, to the extent that the term “includes” is used in either the detailed description or the claims, such term is intended to be inclusive in a manner similar to the term “comprising” as “comprising” is interpreted when employed as a transitional word in a claim. Finally, the term “based on” is interpreted to mean based at least in part.

What is claimed is:

1. A method comprising:
providing an array of electronic devices having leadframes, the leadframes including at least one depopulated lead and external leads interconnected by a first dambar, a second dambar, and a connection assembly, the connection assembly connecting the first dambar to a first external lead of a first leadframe and to a second external lead of a second leadframe, the second leadframe being adjacent to the first leadframe;
performing a first punch process to remove the first dambar and the second dambar from the leadframes;
performing a second punch process to create a cut in the connection assembly proximate the first external lead adjacent to the at least one depopulated lead to disconnect the connection assembly from the first external lead;
performing a trimming process to trim the external leads of the leadframes to their required length; and
removing the connection assembly simultaneously during the trimming process.

2. The method of claim 1, wherein the connection assembly includes a first connection piece connected to the first dambar and extending substantially perpendicular from the first dambar toward the second dambar, and a second connection piece extending from a distal end of the first connection piece substantially perpendicular to the first connection piece, the second connection piece connecting to the first external lead adjacent to the first connection piece.

3. The method of claim 2, wherein a distal end of the second external lead of the second leadframe connects to the second connection piece between the first connection piece and the first external lead.

4. The method of claim 3, wherein performing the second punch process to create the cut in the connection assembly proximate the first external lead the adjacent to the at least one depopulated lead to disconnect the connection assembly from the first external lead includes creating a cut in the second connection piece proximate the first external lead.

5. The method of claim 2, wherein the first connection piece is connected to the first dambar at a location of the at least one depopulated lead.

6. The method of claim 1, wherein performing the first punch process to remove the first dambar and the second dambar from the leadframes forms a first protrusion on a proximate end of either side of the external leads of the leadframes.

7. The method of claim 6, wherein performing the second punch process to create the cut in the connection assembly proximate the first external lead adjacent to the at least one depopulated lead to disconnect the connection assembly from the first external lead forms a second protrusion on the first external lead adjacent to the first protrusion.

8. The method of claim 1, wherein providing the array of electronic devices includes:
providing a leadframe having a die pad and leads comprised of inner leads and the external leads;
placing a die on the die pad via a die attach material;
attaching wire bonds to an active side of the die and to a surface of the inner leads; and
forming a mold compound to encapsulate the die, the die pad, the wire bonds, and the inner leads.

9. An array of electronic devices comprising:
an array of interconnected leadframes including:
at least one depopulated lead;
a first dambar interconnecting external leads on a leadframe and external leads on an adjacent leadframe;
a second dambar interconnecting the external leads on the adjacent leadframe and the external leads on the leadframe; and
a connection assembly, the connection assembly connecting the first dambar to both a first external lead on the leadframe and to a second external lead on the adjacent leadframe; and
a die attached to each of the array of leadframes.

10. The array of electronic devices of claim 9, wherein the connection assembly includes a first connection piece connected to the first dambar in a location of the at least one depopulated lead.

11. The array of electronic devices of claim 10, wherein the first connection piece extends from the first dambar substantially perpendicular to the first dambar.

12. The array of electronic devices of claim 11, wherein the first connection piece is adjacent to the first external lead on the leadframe.

13. The array of electronic devices of claim 12, wherein the connection assembly further includes a second connection piece attached to the first connection piece.

14. The array of electronic devices of claim 13, wherein the second connection piece extends from a distal end of the first connection piece substantially perpendicular to the first connection piece.

15. The array of electronic devices of claim 14, wherein the second connection piece connects to the first external lead of the leadframe.

16. The array of electronic devices of claim 15, wherein a distal end of the second external lead of the adjacent leadframe connects the second connection piece between the first connection piece and the first external lead of the leadframe.

17. The array of electronic devices of claim 9, wherein the first dambar is connected to a proximate end of the external leads on the leadframe.

18. The array of electronic devices of claim 17, wherein the second dambar is connected to a proximate end of the external leads on the adjacent leadframe.

19. The array of electronic devices of claim 9, wherein the die is attached to a die pad of each leadframe of the array of leadframes via a die attach material.

20. An electronic device comprising:
a leadframe having a die pad and leads comprised of at least one depopulated lead, inner leads, and external leads, the external leads including a first protrusion on either side of each of the external leads, and at least one external lead having a second protrusion on each side of the at least one external lead;
a die disposed on the die pad via a die attach material;
wire bonds attached to an active side of the die and to a surface of the inner leads; and
a mold compound encapsulating the die, the die pad, the wire bonds, and the inner leads.

21. The electronic device of claim 20, wherein the second protrusion is adjacent to the first protrusion.

22. The electronic device of claim 20, wherein the at least one depopulated lead is on one side of the leadframe.

23. The electronic device of claim 20, wherein the at least one external lead is adjacent to the at least one depopulated lead.

24. The electronic device of claim 20, wherein the at least one depopulated lead is comprised of a first at least one depopulated lead on one side of the leadframe and a second at least one depopulated lead on an opposite side of the leadframe.

25. The electronic device of claim 24, wherein the at least one external lead is comprised of a first at least one external lead on the one side of the leadframe adjacent to the first at least one depopulated lead, and a second at least one external lead on the opposite side of the leadframe adjacent to the second at least one depopulated lead, the first at least one external lead and the second at least one external lead each including the second protrusion adjacent to the first protrusion.
